(19) United States
(12) Patent Application Publication
(10) Pub. No.: US 2005/0225406 A1
(43) Pub. Date: Oct. 13, 2005

(54) Temperature-compensated quartz-crystal oscillator

(75) Inventors: Hiroyuki Miura, Kokubu-shi (JP); Ryoma Sasagawa, Kokubu-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/041,892

(22) Filed: Jan. 24, 2005

(30) Foreign Application Priority Data
Jan. 29, 2004 (JP) 2004-020785
Jan. 29, 2004 (JP) 2004-020786
Jan. 29, 2004 (JP) 2004-022284
Jun. 29, 2004 (JP) 2004-190922
Jun. 29, 2004 (JP) 2004-190923

(51) Int. Cl. H03L 1/00

(52) U.S. Cl. 331/176

(57) ABSTRACT

The temperature-compensated quartz-crystal oscillator comprises a quartz-crystal oscillation device, a package for accommodating the quartz-crystal oscillation device therein, an IC device for controlling an oscillation output based on oscillation of the quartz-crystal oscillation device, a substrate for attaching the package and mounting the IC device thereon, and a write control terminal for writing temperature compensation data into the IC device. The write control terminal is comprised of a metal body provided on the substrate.

### BACKGROUND OF THE INVENTION

1. Field of the Invention

The present invention relates to a temperature-compensated quartz-crystal oscillator used as a timing device of telecommunication equipment, electronic equipment, or the like.

2. Description of Related Art

Quartz-crystal oscillators have been conventionally used as a timing device of portable telecommunication equipment and the like.

As such a quartz-crystal oscillator, there is known one shown in FIG. 13, for example. (For example, refer to Japanese Unexamined Patent Publication No. 10(1998)-98151). In this quartz-crystal oscillator, a package 123 accommodating a quartz-crystal oscillation device therein is attached on a mounting substrate 121 having a recess 125 in a central region on a top face thereof and a plurality of external terminals on a bottom face thereof. An IC device 126 for controlling an oscillation output on the basis of a resonance frequency of the quartz-crystal oscillation device is accommodated in a region surrounded by the bottom face of the package 123 and an inner face of the recess 125.

A quartz-crystal oscillator as shown in FIGS. 14(a) and 14(b) is also known (Refer to Japanese Unexamined Patent Publication No. 2000-77943). In this quartz-crystal oscillator, the recess 125 is formed in a central region of a bottom face of the mounting substrate 121. The package 123 that accommodates the quartz-crystal oscillation device therein is attached on the mounting substrate 121. The IC device 126 for outputting an oscillation signal on the basis of a resonance frequency of the quartz-crystal oscillation device is accommodated in the recess 125 of the mounting substrate 121.

The package 123 and the mounting substrate 121 are normally formed from a ceramic material such as alumina ceramics. Wiring conductors are formed within and on surfaces of the package 123 and the mounting substrate 121 using a conventionally known green sheet lamination method or the like. On the bottom face of the package 123 and the top face of the mounting substrate 121, respectively, there are provided a plurality of connection electrodes at their corresponding locations and the package 123 is fixed to the top face of the mounting substrate 121 by bonding these connection electrodes to each other by way of a conductive bonding material.

The IC device 126 incorporates therein a temperature-compensating circuit for compensating for the oscillation output of the quartz-crystal oscillator based on temperature compensation data generated based on temperature characteristics of the quartz-crystal oscillation device. A write control terminal 127 is provided on an outer side face of the mounting substrate 121 so as to allow such temperature compensation data to be stored in a memory in the IC device 126. After the assembly of the quartz-crystal oscillator, the temperature compensation data is stored in the memory in the IC device 126 by inputting the temperature compensation data with a probe of a temperature-compensation-data writing device contacted against the write control terminal 127.

A plurality of recesses for arranging the write control terminal 127 thereon are formed on the outer side face of the mounting substrate 121 and the film-like write control terminal 127 is formed by being deposited on an inner side of each recess.

However, to manufacture the mounting substrate 121, it is necessary that the recess is formed on a ceramic motherboard, from which the mounting substrate 121 is cut, and the film-like write control terminal 127 is deposited on the inner side of the recess by applying a conductor paste on the inner side and baking it or further applying metal plating to it. Thus, complicated processes must be done, leading to a drawback of substantially lowering productivity of the temperature-compensated quartz-crystal oscillator.

### SUMMARY OF THE INVENTION

The present invention is devised in light of the above-mentioned drawback and an object thereof is to provide a temperature-compensated quartz-crystal oscillator with excellent productivity.

Another object of the present invention is to provide a temperature-compensated quartz-crystal oscillator without causing a large stray capacitance when being mounted on a motherboard.

Another object of the present invention is to provide a temperature-compensated quartz-crystal oscillator easy to handling at the mounting.

The temperature-compensated quartz-crystal oscillator of the present invention comprises a quartz-crystal oscillation device, a package for accommodating the quartz-crystal oscillation device therein, an IC device for controlling an oscillation output based on a resonant frequency of the quartz-crystal oscillation device, a substrate for supporting the package and mounting the IC device thereon, and a write control terminal formed of a metal body provided on the substrate (for example, a metal pole-like body (metal post)) for writing temperature compensation data into the IC device.

With this configuration, in assembling the temperature-compensated quartz-crystal oscillator, the write control terminal formed of a metal body like a metal post need only to be attached to the substrate to manufacture the temperature-compensated quartz-crystal oscillator. That is, cumbersome processes in forming the film-like write control terminal on an outer side face of the substrate, as in prior art, becomes unnecessary. This enables improvement in productivity of the temperature-compensated quartz-crystal oscillator.

It is preferred that the substrate has a top face, a bottom face and side faces, the write control terminal is disposed on at least either the top face or the bottom face and is not disposed on the side faces.

Further, it is preferred that the package and the substrate are formed so as to have the substantially same dimension in a plan view.

It is preferred that the substrate has a substantially rectangular shape in a plan view and further includes spacer members each disposed at four corners of the substrate and the write control terminal is disposed between the adjacent spacer members.

Furthermore, it is preferred that the package is seated on/fixed to the substrate via a spacer member. In this case, it is preferred that the IC device is mounted on the top face of the substrate on the package's side. It is preferred that the write control terminal is intervened between the package and the substrate and part of the write control terminal is exposed from between the side faces of the package and the substrate.

With this configuration, the write control terminal is disposed on the top face of the substrate and the IC device and the write control terminal are intervened between the substrate and the package. This can prevent a large stray capacitance from occurring between the wiring of the motherboard on which the temperature-compensated quartz-crystal oscillator is implemented and the write control terminal. When the temperature-compensated quartz-crystal oscillator on the motherboard is mounted by way of soldering or the like, part of the molten solder never comes in contact with the write control terminal and causes a short-circuit. This leads to an easy handling of the temperature-compensated quartz-crystal oscillator.

It is preferred that the temperature-compensated quartz-crystal oscillator further includes a connection pad provided on the bottom face of the package. In this case, it is preferred that an upper end of the write control terminal is bonded to the connection pad via a bonding material, thereby achieving mechanical connection of the write control terminal and the package. With this configuration, bonding strength between the substrate and the package can be improved and high reliability of the temperature-compensated quartz-crystal oscillator can be maintained.

In the case where the substrate has a substantially rectangular shape in a plan view, the spacer members are preferably comprised of four metal bodies each attached at four corners on the top face of the substrate on the package's side.

The package may be fixed to the top face of the substrate and the IC device may be attached to the bottom face of the substrate. In this case, it is preferred that the spacer member is attached to the bottom face of the substrate and the write control terminal is attached on an area wherein no spacer member exists in an outer periphery of the bottom face of the substrate, apart from the spacer member. The spacer member acts as a mounting leg bonded to the motherboard and the like.

With this configuration, the write control terminal formed of a metal body such as a metal post or the like is attached to the bottom face of the substrate. Accordingly, in the assembly of the temperature-compensated quartz-crystal oscillator, the write control terminal formed of a metal post or the like need only to be attached to a predetermined position of the bottom face of the substrate to manufacture the temperature-compensated quartz-crystal oscillator. Accordingly, the temperature-compensated quartz-crystal oscillator can be manufactured without requiring cumbersome processes of forming the film-like write control terminal on the side face of the substrate or such.

It is preferred that the lower end of the write control terminal is located upper than the lower end of the spacer member as the mounting leg and coated with an extension of a resin material for sealing the IC device. With this configuration, a certain distance between the wiring of the motherboard on which the temperature-compensated quartz-crystal oscillator is implemented and the write control terminal can be ensured. As a result, a large stray capacitance can be prevented from occurring between them. Further, when the temperature-compensated quartz-crystal oscillator is mounted on the motherboard by way of soldering or the like, the problem that part of the molten solder comes in contact with the write control terminal and causes a short-circuit can be effectively prevented. This leads to an easy handling of the temperature-compensated quartz-crystal oscillator.

In the case where the substrate has a substantially rectangular shape in a plan view, it is preferred that the spacer members are comprised of four metal bodies (for example, metal posts) each attached at four corners on the bottom face of the substrate.

It is preferred that the temperature-compensated quartz-crystal oscillator further includes a resin material that seals the IC device and has an extension extending to the outer periphery of the substrate on its outer periphery. It is preferred that the spacer member have a gap along the top face or the bottom face of the substrate. In this case, preferably, the extension of the resin material enters into the gap of the spacer member and the gap between the spacer member and the write control terminal.

With this configuration, attachment strength of the write control terminal, the spacer member and the like to the substrate can be increased by using the resin material. Moreover, the resin material provides a favorable protection of the circuit formation surface of the IC device, leading to the increased mechanical strength and reliability of the temperature-compensated quartz-crystal oscillator.

In the case where a plurality of the spacer members is provided, the gap may be defined by the adjacent spacer members. One spacer member in the shape of U or C may be arranged along the outer periphery of the substrate. In this case, the spacer member itself may define the gap.

The IC device may be formed of a rectangular flip-chip type IC. In this case, it is preferred that the resin material for sealing the IC device is formed from a transparent material and at least one end face (preferably, two end faces) of the IC device is exposed to an external space from the gap of the spacer member. Accordingly, a junction between the IC device and the substrate can be directly observed. In product inspection, therefore, bonded condition of the IC device can be readily checked by visual inspection or the like. This also contributes to the improved workability of the inspection.

It is preferred that the write control terminal is disposed in the gap of the spacer member on the top face or the bottom face (preferably, its outer periphery) of the substrate. In this case, it is preferred that a distance between the side faces of the write control terminal and the spacer member is set to become greater from the outer side toward the inner side of the substrate and part of the resin material is poured into the gap between the spacer member and the write control terminal.

With this configuration, when the IC device is sealed with the resin material, the liquid resin material can be readily and rapidly poured into the gap between the write control terminal and the spacer member. By thus using the resin material, attachment strength of the write control terminal and the spacer member to the substrate can be increased and the improved mechanical strength and reliability of the temperature-compensated quartz-crystal oscillator can be maintained.

Further, it is preferred that a distance between the side faces of the adjacent write control terminals is set to become greater from the outer side toward the inner side of the substrate and part of the resin material is poured into the gap between the adjacent write control terminals.

With this configuration, the resin material can be readily and rapidly poured into the gap between the adjacent write control terminals. By thus using the resin material, attachment strength of the adjacent write control terminals to the substrate can be increased effectively. As a result, the improved mechanical strength of the temperature-compensated quartz-crystal oscillator can be maintained.

In the case where the substrate has a substantially rectangular shape in a plan view, it is preferred that the number of the write control terminals is set to be 2N (N is natural number) and the 2N write control terminals are disposed in N along two sides of the substrate, which are parallel to each other, symmetrically with respect to a center line parallel to the above-mentioned two sides. With this configuration, when temperature compensation data is written into the IC device with a probe of a temperature-compensation-data writing device contacted against the 2N write control terminals sideways, force from the probe is applied uniformly from both sides of the package. For this reason, it is possible to hold the package in good condition during writing and to effectively prevent damage of the write control terminals due to an unbalanced stress caused by the contact with the probe.

The above-mentioned and other objects, features and effects will appear more fully hereinafter from a consideration of the following description with reference to the accompanying drawings.

### BRIEF DESCRIPTION OF THE DRAWINGS

FIG. 1 is an exploded perspective view of a temperature-compensated quartz-crystal oscillator in accordance with a first embodiment of the present invention.

FIG. 2 is a sectional view of the temperature-compensated quartz-crystal oscillator of FIG. 1.

FIG. 3 is an exploded perspective view illustrating a variant of the temperature-compensated quartz-crystal oscillator in accordance with the first embodiment.

FIG. 4(a) is an exploded perspective view illustrating another variant of the temperature-compensated quartz-crystal oscillator in accordance with the first embodiment and FIG. 4(b) is a plan view of a mounting substrate provided in the quartz-crystal oscillator of FIG. 4(a).

FIGS. 5(a) and 5(b) are views each showing another variant of the first embodiment.

FIG. 6 is an exploded perspective view illustrating an example of a manufacturing method of the temperature-compensated quartz-crystal oscillator in accordance with the first embodiment.

FIG. 7 is an exploded perspective view of a temperature-compensated quartz-crystal oscillator in accordance with a second embodiment of the present invention.

FIG. 8 is a sectional view of the temperature-compensated quartz-crystal oscillator of FIG. 7.

FIG. 9 is a bottom view of the temperature-compensated quartz-crystal oscillator of FIG. 7.

FIG. 10 is a bottom view illustrating a variant of the temperature-compensated quartz-crystal oscillator in accordance with the second embodiment.

FIG. 11 is a bottom view illustrating another variant of the temperature-compensated quartz-crystal oscillator in accordance with the second embodiment.

FIGS. 12(a) and 12(b) are bottom views each showing another variant of the second embodiment.

FIG. 13 is an exploded perspective view illustrating a prior art.

FIG. 14(a) is an exploded perspective view illustrating another prior art and FIG. 14(b) is a perspective view showing a vertically-flipped mounting substrate of this prior art.

### DETAILED DESCRIPTION OF THE INVENTION

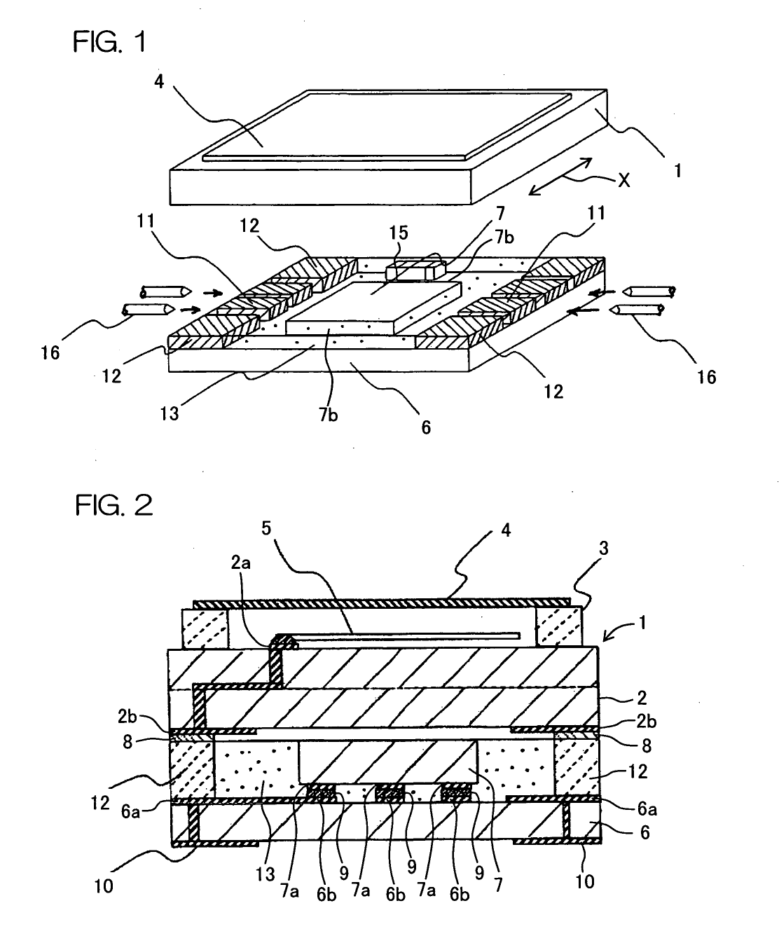

FIG. 1 is an exploded perspective view of a temperature-compensated quartz-crystal oscillator in accordance with a first embodiment of this invention, and FIG. 2 is a sectional view of the temperature-compensated quartz-crystal oscillator of FIG. 1. This temperature-compensated quartz-crystal oscillator has a configuration wherein a rectangular package 1 having a quartz-crystal oscillation device 5 therein is seated on/fixed to a rectangular mounting substrate 6 via spacing members 12. The mounting substrate 6 has a plurality of external terminals 10 on its bottom face and an IC device 7 on its top face.

The package 1 includes a substrate 2 formed from a ceramic material such as glass ceramic and alumina ceramics, a seal ring 3 formed from a metal such as 42 alloy, kovar and phosphor bronze, and a closure 4 formed from the same metal as the seal ring 3. The package 1 is configured by attaching the seal ring 3 on a top face of the substrate 2 and mounting/fixing the closure 4 on/to a top face of the seal ring 3. The quartz-crystal oscillation device 5 is implemented on the top face of the substrate 2 inner from the seal ring 3.

The package 1 serves to accommodate the quartz-crystal oscillation device 5 therein, more specifically, in a space enclosed by the top face of the substrate 2, inner side faces of the seal ring 3 and a bottom face of the closure 4 for hermetic sealing. On the top face of the substrate 2, there are provided a pair of mounting pads 2a connected to oscillating electrodes of the quartz-crystal oscillation device 5 and on the bottom face of the substrate 2, there are provided a plurality of connection electrodes 2b connected to the spacer members 12 described later. The respective pads 2a and connection electrodes 2b are electrically connected to each other via wiring conductors on the surface of the substrate 2 and a via hole conductor within the substrate 2.

In the case where the substrate 2 of the container 1 is formed from ceramic material such as glass ceramic and alumina ceramics, the substrate 2 may be produced as follows, for example. A conductive paste to define a wiring conductor (wiring pattern) is applied to a surface of a ceramic green sheet formed from a mixture including ceramic powder, a suitable organic solvent and the like by the conventionally known screen printing method or the like. The ceramic green sheet is stacked on multiple layers and press-formed into a laminate of ceramic green sheets. The laminate of ceramic green sheets is sintered at high temperatures so as to form the substrate 2.

The seal ring 3 and the closure 4 are manufactured using the conventionally known metal working method wherein a metal such as 42 alloy is worked into a predetermined shape. The seal ring 3 thus obtained is brazed to a conductive layer previously deposited on the top face of the substrate 2. Subsequently, after implementing/fixing the quartz-crystal oscillation device 5 on the top surface of the substrate 2 by use of a conductive adhesive, the closure 4 is bonded to the top face of the seal ring 3 by conventionally known resistance welding or the like to assemble the package 1. In the case of bonding the seal ring 3 and the closure 4 by resistance welding or the like in this manner, a Ni-plate layer or Au-plate layer is previously deposited on surfaces of the seal ring 3 and the closure 4.

On the other hand, the quartz-crystal oscillation device 5 accommodated in the package 1 is formed by depositing a pair of oscillation electrodes on either main planes of a quartz slice obtained by cutting quartz from a predetermined crystal axis. When an external voltage is applied to the quartz slice via the pair of oscillation electrodes, the quartz slice encounters thickness shear oscillations at given frequencies.

By electrically connecting the pair of oscillation electrodes with the respective mounting pads on the top face of the substrate 2 via the conductive adhesive, the quartz-crystal oscillation device 5 is mounted on the top face of the substrate 2. As a result, electrical and mechanical connection between the quartz-crystal oscillation device 5 and the package 1 can be accomplished simultaneously.

It is preferred that the closure 4 of the package 1 is electrically connected with the ground terminal of the external terminals 10 via the wiring conductor (wiring pattern or the like) of the package 1 and the mounting substrate 6, the external terminals disposed on the bottom face of the mounting substrate 6. This connection provides the grounding of the closure 4 so that the closure 4 can have a shielding function. Accordingly, the quartz-crystal oscillation device 5 and the IC device 7 described later can be preferably protected from unwanted external electrical effects.

The mounting substrate 6 that the package 1 is seated on/fixed to has a substantially rectangular shape with the substantially same size as the package 1 and overlaps the package 1 in a plan view. The spacer members 12 each are attached and vertically arranged at four corners on the top face of the mounting substrate 6 and the IC device 7 is mounted in the center region surrounded by the spacer members 12 on the top face of the mounting substrate 6.

The mounting substrate 6 serves to support the package 1 through the IC device 7 and the spacer members 12 on the top face thereof. The mounting substrate 6 is formed in a flat plane using any of the following materials including glass-cloth based resins, resin materials such as polycarbonate, epoxy resins and polyimide resins, and ceramic materials such as glass-ceramics and alumina-ceramics.

The spacer members 12 vertically arranged on the top face of the mounting substrate 6 each are formed of a metal post (an example of a metal body) obtained by forming a metal material such as copper in a square pole. The spacer member 12 each are electrically and mechanically connected with wiring conductors 6a of the mounting substrate 6 at the lower end thereof and with connection electrodes 2b on the bottom face of the package 1 via conductive bonding materials 8 such as solder at the upper end thereof.

To achieve a good bonding condition of the conductive bonding materials with the package 1, a Ni-plate layer or Au-plate layer with a predetermined thickness is deposited on the top faces of the spacer members 12.

The mounting substrate 6 is provided with four external terminals 10 (a source voltage terminal, a ground terminal, an oscillation output terminal and an oscillation control terminal) on the bottom face thereof. When the temperature-compensated quartz-crystal oscillator is mounted on external electrical circuits such as a motherboard (not shown), these external terminals 10 are electrically connected with circuit wirings of the external electrical circuits by means of soldering or the like.

Preferably, out of the four external terminals 10, the ground terminal and the oscillation output terminal are arranged adjacent to each other. This arrangement can effectively prevent noise from interfering with an oscillation signal output from the oscillation output terminal.

A plurality of electrode pads 6b are formed by being deposited in a center region of the top face of the mounting substrate 6 and the IC device 7 is mounted in the region wherein the electrode pads 6b are formed.

The IC device 7 may employ a rectangular flip-chip type IC on a bottom face thereof, which includes a plurality of connection pads 7a each corresponding to the respective electrode pads 6b of the mounting substrate 6. On the circuit formation surface (bottom face) of the IC device 7, there is provided a temperature sensor (thermistor) for sensing the ambient temperatures, a memory for storing temperature compensation data for compensating for temperature characteristics of the quartz-crystal oscillation device 5, a temperature compensating circuit operating based on the temperature compensation data thereby compensating for the temperature characteristics of the quartz-crystal oscillation device 5 according to the temperature variations, an oscillation circuit connected with the temperature compensation circuit and operative to generate a predetermined oscillation output, and the like. The oscillation output generated by the oscillation circuit is output externally and then is used as a reference signal such as a clock signal.

Two end faces 7b, 7b of the IC device 7 disposed in substantially parallel relation are exposed to an external space between the adjoining spacer members 12, the end faces being coated with a resin material 13. These two end faces 7b are located along an outer periphery of the mounting substrate 6 slightly inwardly of outer peripheries of the package 1 and the mounting substrate 6, say 1 μm to 500 μm inwardly of the outer periphery of the mounting substrate 6. In this case, a widthwise dimension of the mounting substrate 6 with respect to a direction X orthogonal to the pair of end faces 7b, 7b of the IC device 7 is designed to be substantially equal to the length of one side of the IC device 7. Therefore, the whole structure of the temperature-compensated quartz-crystal oscillator can be reduced in size.

A chip component (electronic devices other than the IC device) such as a chip capacitor 15 for noise removal may be disposed on the top face of the mounting substrate 6 between adjoining spacer members 12, 12. In FIG. 1, the chip capacitor 15 is arranged so as to be adjacent to one of the pair of end faces 7b, 7b. In this case as well, the temperature-compensated quartz-crystal oscillator can be reduced in size by arranging the other end face 7b so as to be extremely adjacent to the outer periphery of the mounting substrate 6.

The connection pads 7a formed on the bottom face of the IC device 7 are individually connected to the corresponding electrode pads 6b on the top face of the mounting substrate 6 via the conductive bonding material 9 such as a solder and gold bump. This allows the IC device 7 to be attached to the mounting substrate 6, whereby predetermined circuits in the IC device 7 are electrically connected with the quartz-crystal oscillation device 5, the external terminals 10 and the like via the wiring conductors through the package 1, the wiring conductors through the mounting substrate 6 and the like.

When the mounting substrate 6 is formed using a glass-cloth based epoxy resin, a base of the substrate is formed by impregnating a glass-cloth base with a liquid precursor and polymerizing the precursor at high temperatures, the glass-cloth base formed by weaving glass fiber. The spacer members 12 in the form of metal posts and the wiring conductors 6a are formed by applying a metal foil such as a copper foil to a surface of the base and patterning the base into a predetermined wiring pattern by using a conventionally known photoetching method or the like.

When the package 1 is seated on/fixed to the mounting substrate 6 via the spacer members 12, the top faces of the spacer members 12 are contacted against the corresponding connection electrodes 2b on the bottom face of the package 1 via the conductive bonding material 8 such as a solder. Subsequently, the conductive bonding material 8 is molten by heating or such, thereby electrically and mechanically connecting the spacer members 12 to the connection electrodes 2b via the conductive bonding material 8. This allows the package 1 to be attached to the mounting substrate 6.

A plurality of write control terminals 11 for writing the temperature compensation data into the IC device 7 are intervened between the package 1 and the mounting substrate 6.

Similarly to the spacer members 12 described above, the write control terminals 11 each are formed of a metal post (an example of a metal body) obtained by forming a metal material such as copper in the shape of a pole. The write control terminals 11 are attached to the top face of the mounting substrate 6 so that part of each side face is exposed to an external space between side faces of the package 1 and the mounting substrate 6.

The spacer members 12 and the write control terminals 11 may be arranged on the mounting substrate 6 using the same forming method. For example, the spacer members 12 and the write control terminals 11 may be formed together in one operation by forming a metal film on the whole top face of the mounting substrate 6 and then patterning it by etching. In this case, the metal film may be a single-layer film or a multilayer film wherein a plurality of metal layers are laminated. Alternatively, by selectively developing the metal film on the mounting substrate 6, the spacer members 12 and the write control terminals 11 may be formed together in one operation. Furthermore, in the case where the metal film is a single-layer film, the spacer members 12 and the write control terminals may be also formed together in one operation by printing a metal material on the top face of the mounting substrate 6 in a predetermined pattern to form a metal film pattern. In another method, metal pieces are adhered to predetermined positions on the top face of the mounting substrate 6 and the metal pieces are used as the spacer members 12 and the write control terminals 11.

The spacer members 12 and the write control terminals 11 need not be formed in the shape of a precise pole and may be shaped like a cone (for example, quadrangular pyramid, truncated cone). More specifically, the spacer members 12 and the write control terminals 11 may be formed by so-called bump.

The write control terminals 11 are provided along an edge of the mounting substrate 6 and electrically connected with the IC device 7 via the wiring conductors 6a through the mounting substrate 6 and the like. In this embodiment, the number of the write control terminals 11 is set to be 2N (N is natural number), say 4. The four write control terminals 11 are disposed in twos along two sides of the mounting substrate 6, which are parallel to each other, symmetrically with respect to a center line parallel to the two sides.

After the assembly of the temperature-compensated quartz-crystal oscillator, the temperature compensation data is stored into the memory in the IC device 7 by inputting the temperature compensation data with a probe 16 of a temperature-compensation-data writing device contacted against the write control terminals 11 sideways.

At this time, since the four write control terminals 11 are disposed in twos along two sides of the mounting substrate 6, which are parallel to each other, symmetrically with respect to a center line parallel to the two sides, force from the probe 16 is applied uniformly from both sides of the mounting substrate 6 and the package 1. For this reason, it is possible to hold the mounting substrate 6 and the package in good condition during writing and to effectively prevent damage of the write control terminals 11 due to an unbalanced stress caused by the contact with the probe 16, thereby carrying out a stable writing operation.

The outer side face of each write control terminal 11 must have an enough area to be contacted with the probe 16. To meet the requirement, it is preferred that the write control terminals 11 each have a height (thickness) of 0.2 mm or more (more preferably, 0.3 mm or more). However, the height (thickness) of the write control terminals 11 is set so as not to exceed the height (thickness) of the spacer members 12.

The upper ends of the write control terminals 11 are bonded to dummy connection pads (not shown) provided on the bottom face of the package 1 via a bonding material. It is preferred to mechanically connect the write control terminals 11 with the package 1 in this manner. This enables increase in bonding strength between the mounting substrate 6 and the package 1, thereby maintaining improved reliability of the temperature-compensated quartz-crystal oscillator.

A resin material 13 for sealing the IC device 7 is formed of epoxy resin, for example. An outer periphery of the resin material 13 forms an extension extending to the outer periphery of the mounting substrate 6. The extension enters into (preferably, fills) each gap between adjacent spacer members 12 or between the spacer member 12 and the write control terminal 11 and its part is deposited on the above-mentioned end faces 7b of the IC device 7.

By letting (preferably, filling) the resin material 13 into each gap between adjacent spacer members 12, 12 or between the spacer member 12 and the write control terminal 11 in this manner, attachment strength of the IC device 7, the write control terminals 11 and the spacer members 12 to the mounting substrate 6 can be increased. In addition, the resin material 13 provides a favorable protection of the circuit formation surface of the IC device 7, leading to the increased mechanical strength and reliability of the temperature-compensated quartz-crystal oscillator.

It is preferred that the resin material 13 is formed from a transparent material. In this case, even when the end face 7b of the IC device 7 exposed to external space from between the adjacent spacer members 12, 12 is coated with the resin material 13, a junction between the IC device 7 and the mounting substrate 6 can be directly observed through the transparent resin material 13. In product inspection, therefore, bonded condition of the IC device 7 can be readily checked by visual inspection or the like. This also contributes to the improved workability of the inspection.

Thus, the above-mentioned temperature quartz-crystal oscillator is mounted on the external wiring substrate such as a motherboard by means of soldering or the like and carries out its functions by outputting a given oscillation signal depending on a resonance frequency of the quartz-crystal oscillation device 5 while correcting the oscillation output by a temperature compensating circuit of the IC device 7.

In the temperature-compensated quartz-crystal oscillator of this embodiment as described above, the write control terminals 11 for writing temperature compensation data into the IC device 7 each are formed of a metal post and part of the write control terminals 11 is exposed to outside from between the side faces of the package 1 and the mounting substrate 6. With this configuration, in assembling the temperature-compensated quartz-crystal oscillator, the write control terminals 11 formed of metal posts need only to be attached to predetermined positions of the top face of the mounting substrate 6 to manufacture the temperature-compensated quartz-crystal oscillator. Accordingly, cumbersome processes of forming recesses on the outer side face of the mounting substrate 6 and forming film-like write control terminals on the inner wall of the recesses become unnecessary. This enables improvement in productivity of the temperature-compensated quartz-crystal oscillator.

Moreover, since the write control terminals 11 are attached to the top face of the mounting substrate 6, there occurs no large stray capacitance between wiring of the motherboard on which the temperature-compensated quartz-crystal oscillator is mounted and the write control terminals 11. As a matter of course, when the temperature-compensated quartz-crystal oscillator is mounted on the motherboard, part of the molten solder never comes in contact with the write control terminals 11 and causes a short-circuit. This leads to an easy handling of the temperature-compensated quartz-crystal oscillator.

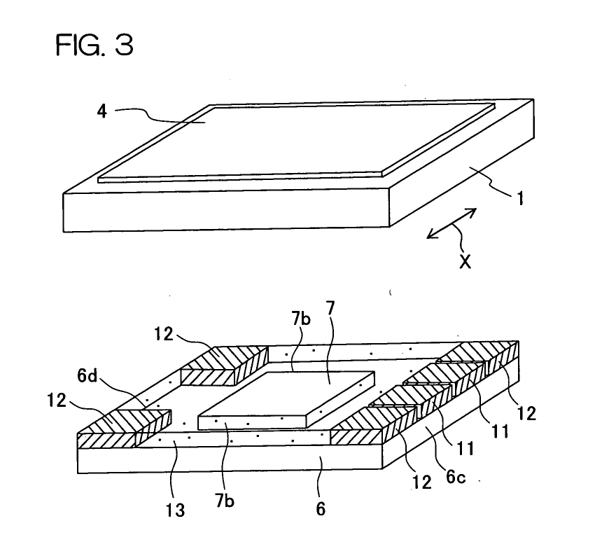

FIG. 3 is an exploded perspective view illustrating a variant of the temperature-compensated quartz-crystal oscillator in accordance with the above-mentioned first embodiment. In the above-mentioned embodiment, the plurality of write control terminals 11 are divided into two groups and the groups are arranged along the two sides of the mounting substrate 6, which are parallel to each other, respectively. On the contrary, in the variant shown in FIG. 3, the plurality of write control terminals 11 are aligned along a side 6c of the mounting substrate 6. In this case, a space is generated between the spacer members 12, 12 disposed at both ends of a side 6d opposed to the side 6c. A chip component such as a chip capacitor may be disposed in the space. Therefore, since the pair of end faces 7b of the IC chip 7 are readily designed to be disposed in close vicinity to the outer periphery of the mounting substrate 6, the dimension of the temperature-compensated quartz-crystal oscillator in X direction can be substantially equal to the IC ship 7.

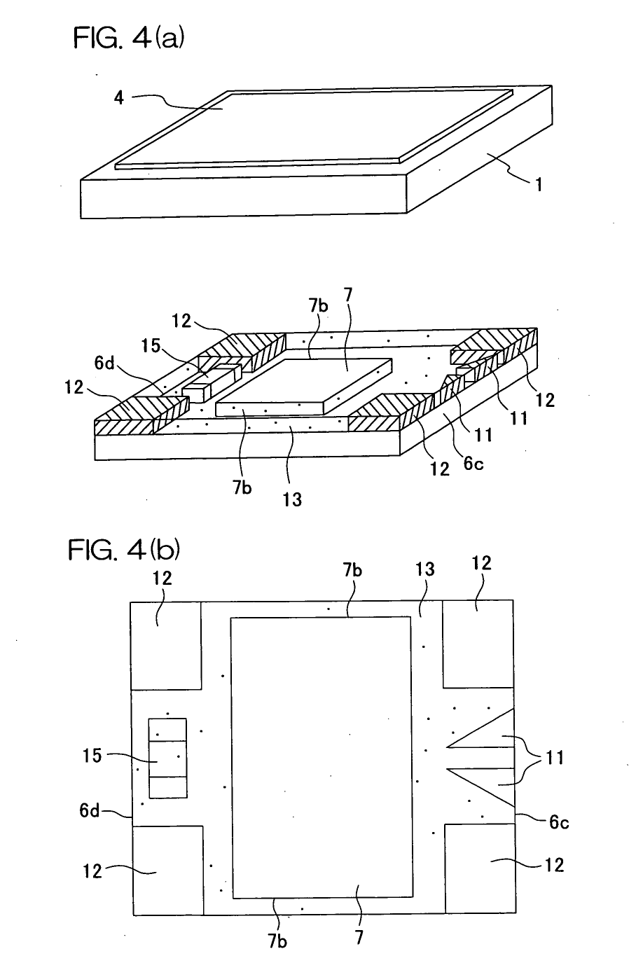

FIG. 4(a) is an exploded perspective view illustrating another variant of the temperature-compensated quartz-crystal oscillator in accordance with the above-mentioned first embodiment and FIG. 4(b) is a plan view of a mounting substrate provided in the quartz-crystal oscillator of FIG. 4(a). In this variant, as in the case of FIG. 3, the write control terminals 11 are aligned along the side 6c of the mounting substrate 6 and no write control terminal 11 is provided in the vicinity of a side 6d opposed to the above-mentioned side 6c. In a space defined between the spacer members 12, 12 disposed at both ends of the side 6d, a chip component (electronic devices other than the IC device) such as the chip capacitor 15 is attached to the top face of the mounting substrate 6. The pair of end faces 7b, 7b of the IC chip 7 are disposed in close vicinity of the mounting substrate 6.

This variant is characterized by the shape of the write control terminals 11. Like the spacer members 12, the write control terminals 11 each are shaped as a metal post in the shape of a triangle pole by processing a metal material such as copper using a conventionally known photoetching method. One side face of each write control terminal 11 is fixed to the top face of the mounting substrate 6 so as to be exposed to outside from between the side faces of the package 1 and the mounting substrate 6.

A particularly important feature of this variant is that a gap between the write control terminal 11 like a triangle pole and the side face of the spacer member 12 is set to become narrower from the side of the IC device 7 toward the side of the edge of the mounting substrate 6. Accordingly, when the IC device 7 is sealed with the resin material 13, the liquid resin material 13 can be favorably penetrated and poured into each gap between the spacer member 12 and the write control terminal 11. As a result, by favorably letting (preferably, filling) the resin material 13 into the gap between the spacer member 12 and the write control terminal 11, attachment strength of the write control terminals 11 and the spacer members 12 to the mounting substrate 6 can be increased more effectively.

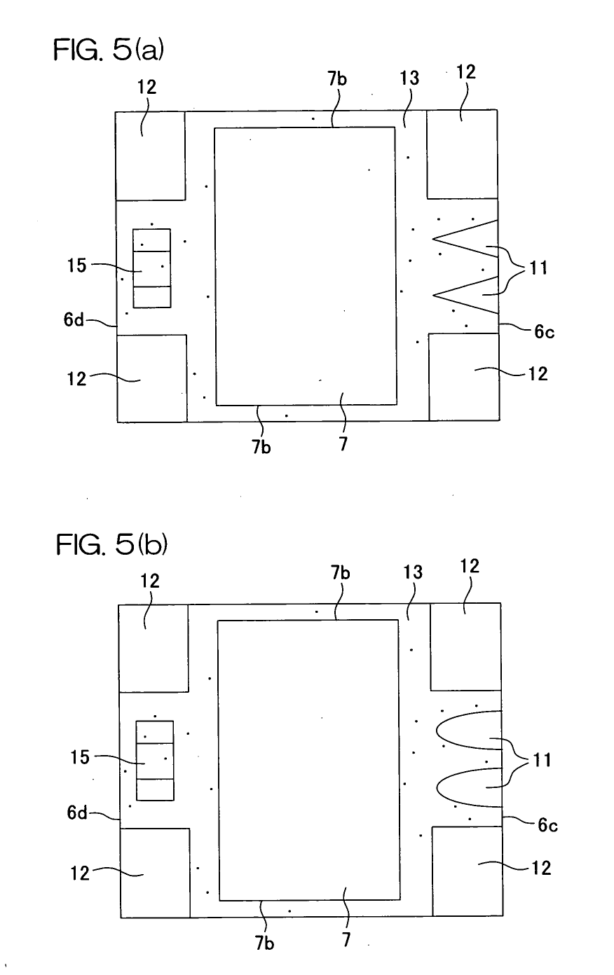

In the example shown in FIGS. 4(a) and 4(b), opposing side faces of the adjacent write control terminals 11 are parallel to each other. Instead of this, as shown in FIG. 5(a), a distance between the opposing side faces of the adjacent write control terminals 11 may be set to become greater from the outer side toward the inner side of the mounting substrate 6. In this case, the resin material 13 can be readily and rapidly poured into the gap between the adjacent write control terminals 11. This results in more productive filling of the resin material 13 and more effective improvement in attachment strength of the write control terminals 11 to the mounting substrate 6.

Further, the write control terminals 11 having a shape other than a triangle pole can achieve the similar effect. For example, the write control terminals 11 each may be formed of a metal post in the shape of a semicircular column as shown in FIG. 5(b) or of a square pole having a bottom face of trapezoid.

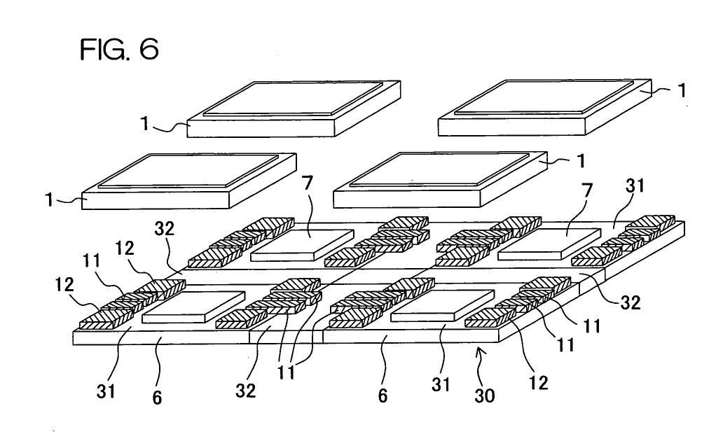

FIG. 6 is an exploded perspective view illustrating an example of a preferred manufacturing method of the above-mentioned temperature-compensated quartz-crystal oscillator in accordance with the first embodiment. The manufacturing method of the temperature-compensated quartz-crystal oscillator shown in FIG. 6 comprises a step of preparing a master substrate 30 wherein a rectangular substrate region 31 and a rectangular throw-away region 32 are alternately arranged in adjoining relation, a step of attaching a plurality of the spacer members 12 to corners of each substrate region 31 and of attaching the write control terminal 11, one end of which extends to the throw-away region 32, to a space between the adjacent spacer members 12 in the same substrate region 31, a step of mounting the IC device 7 on an area wherein no spacer members 12 and write control terminal 11 exists in each substrate region 31 of the master substrate 30 and then attaching the package 1 accommodating the quartz-crystal oscillation device 5 therein on the spacer members 12, a step of writing temperature compensation data into the IC device 7 via the extension of the write control terminal 11 disposed on the throw-away region 32, and a step of obtaining a plurality of temperature-compensated quartz-crystal oscillators wherein a cut face of the write control terminal 11 is exposed by cutting the master substrate 30 along the outer periphery of each substrate region 31 and separating each substrate region 31 from the throw-away region 32. According to the manufacturing method, since part of the write control terminal 11 provided in each substrate region 31 of the master substrate 30 extends to the throw-away region 32, the temperature compensation data can be written into the IC device 7 of each substrate region 31 in one operation with the probe of the temperature-compensation-data writing device contacted against the extension. This enables simplification of the manufacturing process of the temperature-compensated quartz-crystal oscillator.

According to a variant of this manufacturing method, the temperature compensation data may be written into the IC device 7 by providing a write control pad, which is electrically connected with the write control terminal 11 via a via conductor formed on the master substrate 30, on a main face (bottom face of the master substrate) on the other side of a mounting face of the IC device 7 of the master substrate 30 in the throw-away region 32 and bringing the probe of the temperature-compensation-data writing device into contact with the write control pad from the bottom face of the master substrate 30. In this case, since the probe of the temperature-compensation-data writing device can be brought into contact with the write control pad from the bottom face of the master substrate 30 on which there exists no package 1 and the like, the inconvenience that probe comes into contact with the package 1 and the like can be obviated. This leads to easy writing operation of the temperature compensation data.

The following modifications may be also made to the above-mentioned first embodiment.

For example, in the above-mentioned embodiment, the spacer members 12 each are formed of a metal post. Instead of this, however, the spacer members 12 may be formed integral with the mounting substrate 6 by using the same insulating material as that of the mounting substrate 6. In this case, connection pads for electrically and mechanically connecting the spacer members 12 via the connecting electrodes 2b on the bottom face of the package 1 and the conductive bonding material 8 are provided on the top end faces of the spacer member 12. Further, it is preferred that wiring conductors for electrically connecting the connecting pads with the wiring conductors 6a on the mounting substrate 6 are formed on the side faces of the spacer members 12.

The conductive bonding material 8 used for bonding the package 1 to the spacer members 12 on the mounting substrate 6 is not limited to a general conductive material such as a solder. For example, an aristropic conductive bonding material may be used as the conductive bonding material 8. In this case, attachment operation of the package 1 to the mounting substrate 6 becomes extremely simple and hence, the assembling process of the temperature-compensated quartz-crystal oscillator is further simplified.

In the above-mentioned embodiment, four spacer members 12 are attached at four corners on the top face of the mounting substrate 6. However, the number of the spacer members 12 is not limited to four. For example, in the case where the spacer member 12 is formed from the same insulating material as that of the mounting substrate 6, the package 1 may be supported by one spacer member 12 formed in the shape of U along the outer periphery of the mounting substrate 6. In this case, the write control terminal 11 may be disposed in a gap defined by the spacer member 12 in the shape of U on the outer periphery of the mounting substrate 6. As a matter of course, the package 1 may be supported by two, three, five or more spacer members 12.

In the above-mentioned embodiment, the mounting substrate 6 that the package 1 is seated on/fixed to has the substantially same dimension as the package 1 in a plan view. However, the package 1 is not be necessarily exactly the same as the mounting substrate 6 in size. Specifically, the length and width dimensions of the package 1 only need to be set in the range between 85 to 100% with respect to those of the mounting substrate, respectively.

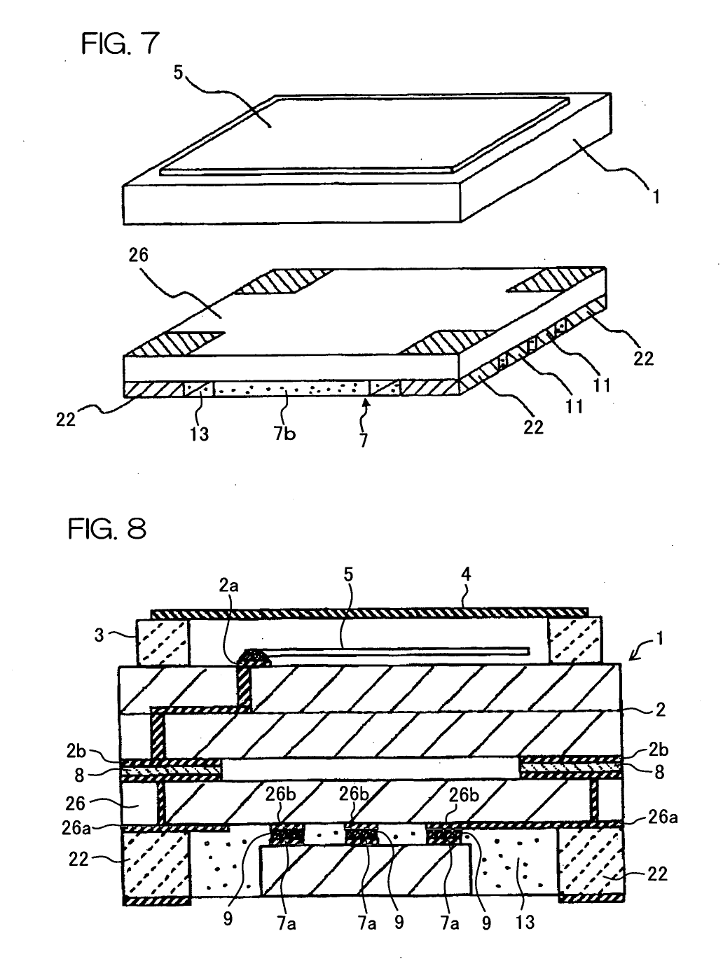

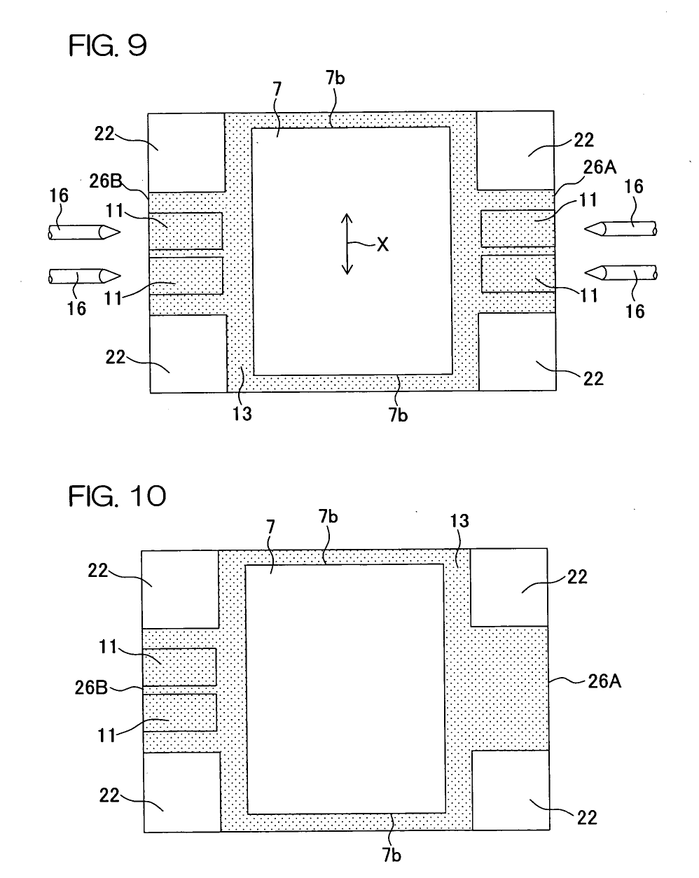

FIG. 7 is an exploded perspective view of a temperature-compensated quartz-crystal oscillator in accordance with a second embodiment of the present invention. FIG. 8 is a sectional view of the temperature-compensated quartz-crystal oscillator of FIG. 7. FIG. 9 is a bottom view of the temperature-compensated quartz-crystal oscillator of FIG. 7 when viewed from the bottom. In these figures, the same reference numerals are used to designate the same or similar components as those in FIGS. 1 and 2. For the same or similar components as those in the first embodiment, description thereof will be partly omitted for avoiding overlaps as much as possible.

The temperature-compensated quartz-crystal oscillator of this embodiment has the rectangular package 1 accommodating the quartz-crystal oscillation device 5 therein and a supporting substrate 26 for supporting the package 1. The IC device 7 and a plurality of the mounting legs 22 as spacer members are attached to a bottom face of the supporting substrate 26. The configuration of the package 1 is similar to that as in the first embodiment.

It is preferred that the closure 4 of the package 1 is electrically connected with the ground mounting legs 22 via wiring conductors 26a (wiring pattern or the like) of the package 1 and the supporting substrate 26, the ground mounting legs disposed on the bottom face of the mounting substrate 6. This connection provides the grounding of the closure 4 so that the closure 4 can have a shielding function. Accordingly, the quartz-crystal oscillation device 5 and the IC device 7 can be preferably protected from unwanted external electrical effects.

The supporting substrate 26 that the package 1 is seated on/fixed to has a substantially rectangular shape with the substantially same size as the package 1 and overlaps the package 1 in a plan view. The plurality of mounting legs 22 and the plurality of write control terminals 11 are attached along the outer periphery on the bottom face of the supporting substrate 26. In this embodiment, the mounting legs 22 are individually attached and vertically arranged at four corners on the bottom face of the supporting substrate 26. In the vicinity of a side 26A of the supporting substrate 26, the two write control terminals 11 are arranged adjacent to each other in a gap between a pair of adjacent mounting legs 22 (disposed at both ends of the side 26A). Further, in the vicinity of a side 26B opposed to the side 26A, other two write control terminals 11 are arranged adjacent to each other in a gap between another pair of adjacent mounting legs 22 (disposed at both ends of the side 26B). On the bottom face of the supporting substrate 26, the IC 7 is mounted in a center region surrounded by the four (2×2) mounting legs 22 and the four write control terminals 11.

The supporting substrate 26 serves to support the above-mentioned package 1 on the top face thereof and to allow the IC device 7, the write control terminals 11 and the mounting legs 22 to be attached on the bottom face thereof. The supporting substrate 26 is formed in a flat plane using any of the following materials including glass-cloth based resins, resin materials such as polycarbonate, epoxy resins and polyimide resins, and ceramic materials such as glass-ceramics and alumina-ceramics.

The plurality of supporting legs 22 attached to/vertically arranged on the top face of the supporting substrate 26 each are formed of a metal post (an example of a metal body) obtained by forming a metal material such as copper in shape of a square pole. The mounting legs 22 act as external terminals. That is, when the temperature-compensated quartz-crystal oscillator is mounted on external wiring substrates such as a motherboard (not shown), the mounting legs 22 are electrically connected with circuit wirings of external electrical circuits by means of soldering or the like.

The four mounting legs 22 each function as a source voltage terminal, a ground terminal, an oscillation output terminal and an oscillation control terminal, respectively. To achieve a good bonding condition of the soldering and the like with the external wiring substrate, a Ni-plate layer, Au-plate layer or the like with a predetermined thickness is deposited on the bottom face of these mounting legs 22.

Preferably, out of the four mounting legs 22, the ground mounting leg 22 and the oscillation output leg 22 are arranged adjacent to each other. This arrangement can effectively prevent noise from interfering with an oscillation signal output from the oscillation output terminal.

Two end faces 7b, 7b of the IC device 7 disposed in substantially parallel relation are exposed to an external space between the adjoining mounting legs 22, the end faces being coated with a resin material 13. These two end faces 7b are located along an outer periphery of the supporting substrate 26 slightly inwardly of outer peripheries of the package 1 and the supporting substrate 26, say 1 μm to 500 μm inwardly of the outer periphery of the supporting substrate 6. In this case, a widthwise dimension of the supporting substrate 26 with respect to a direction X orthogonal to the pair of end faces 7b, 7b of the IC device 7 is designed to be substantially equal to the length of one side of the IC device 7. Therefore, the whole structure of the temperature-compensated quartz-crystal oscillator can be reduced in size.

A plurality of electrode pads 26b are formed by being deposited in a center region of the bottom face of the supporting substrate 26 and the IC device 7 is mounted in the region wherein the electrode pads 26b are formed. That is, the connection pads 7a formed on the circuit formation face of the IC device 7 each are connected with the corresponding electrode pads 26b via the conductive bonding materials 9 such as a solder and gold bump. This allows the IC device 7 to be attached/implemented to the bottom face of the supported substrate 26, whereby predetermined circuits in the IC device 7 are electrically connected with the quartz-crystal oscillation device 5, the mounting legs 22 and the like via the wiring conductors through the package 1, the wiring conductors through the supporting substrate 26 and the like.

When the supporting substrate 26 is formed using a glass-cloth based epoxy resin, a base of the substrate is formed by impregnating a glass-cloth base with a liquid precursor and polymerizing the precursor at high temperatures, the glass-cloth base formed by weaving glass fiber. The mounting legs 22 formed of metal posts and the wiring conductors 26a are formed by applying a metal foil such as a copper foil to a surface of the base and patterning the base into a predetermined wiring pattern by using a conventionally known photoetching method or the like.

The plurality of write control terminals 11 for writing temperature compensation data into the IC device 7 are attached on the bottom face of the supporting substrate 26.

Like the above-mentioned mounting legs 22, the write control terminals 11 each are formed of a metal post (an example of a metal body) obtained by forming metal material such as copper in shape of a square pole. The length dimension of the write control terminal 11 is set slightly short so that its lower end is located upper than the lower end of the mounting leg 22. Each write control terminal 11 is attached to the bottom face of the supporting substrate 26 so that part of the side face is exposed to an external space from between the adjacent mounting legs 22.

The mounting legs 22 and the write control terminals 11 may be disposed on the bottom face of the supporting substrate 26. For example, the spacer members 12 and the write control terminals 11 may be formed together in one operation by forming a metal film on the whole bottom face of the supporting substrate 26 and then patterning it by etching. In this case, the metal film may be a single-layer film or a multilayer film wherein a plurality of metal layers are laminated. Further, by selectively developing the metal film on the supporting substrate 26, the spacer members 12 and the write control terminals 11 may be formed together in one operation. Furthermore, in the case where the metal film is a single-layer film, the spacer members 12 and the write control terminals 11 may be also formed together in one operation by printing a metal material on the top face of the supporting substrate 26 in a predetermined pattern to form a metal film. In another method, metal pieces are adhered to predetermined positions on the top face of the supporting substrate 26 and the metal pieces are used as the spacer members 12 and the write control terminals 11.

The mounting legs 22 and the write control terminals 11 need not be formed in the shape of a precise square pole and may be shaped like a cone (for example, quadrangular pyramid, truncated cone). More specifically, the mounting legs 22 and the write control terminals 11 may be formed by so-called bump.

The write control terminals 11 are provided along an edge of the supporting substrate 26 and electrically connected with the IC device 7 via the wiring conductors 26a through the supporting substrate 26 and the like. In this embodiment, the number of the write control terminals 11 is set to be 2N (N is natural number), say 4. The four write control terminals 11 are disposed in twos along two sides of the supporting substrate 26, which are parallel to each other, symmetrically with respect to a center line parallel to the two sides.

After the assembly of the temperature-compensated quartz-crystal oscillator, the temperature compensation data is stored into the memory in the IC device 7 by inputting the temperature compensation data with a probe 16 of a temperature-compensation-data writing device contacted against the write control terminals 11 sideways.

At this time, since the four write control terminals 11 are disposed in twos along two sides of the supporting substrate 26, which are parallel to each other, symmetrically with respect to a center line parallel to the two sides, force from the probe 16 is applied uniformly from both sides of the supporting substrate 6 and the package 1. For this reason, it is possible to hold the supporting substrate 26 and the package 1 in good condition during writing and to effectively prevent damage of the write control terminals 11 due to an unbalanced stress caused by the contact with the probe 16.

The outer side face of each write control terminal 11 must have an enough area to be contacted with the probe 16. To meet the requirement, it is preferred that the write control terminals 11 each have a height (thickness) of 0.2 mm or more (more preferably, 0.3 mm or more). However, the height (thickness) of the write control terminals 11 is set to be less than the height (thickness) of the mounting legs 22.

In the temperature-compensated quartz-crystal oscillator of this embodiment as described above, the write control terminals 11 are integrated with other components only by attaching the write control terminals 11 to predetermined positions on the bottom face of the supporting substrate 26. Accordingly, cumbersome processes of forming recesses on the outer side face of the supporting substrate 26 and forming film-like write control terminals on the inner wall of the recesses become unnecessary. This enables improvement in productivity of the temperature-compensated quartz-crystal oscillator.

The resin material 13 for sealing the IC device 7 has an extension extending to an outer periphery of the supporting substrate 26. This extension enters into (preferably, fills) each gap between the adjacent mounting legs 22 or between the mounting leg 22 and the write control terminal 11 and part of the extension is deposited on the above-mentioned exposed faces of the IC device 7. Since the write control terminal 11 is set shorter than the mounting leg 22, the resin material 13 is also deposited on the bottom faces of the write control terminals 11.

By letting (preferebly, filling) the resin material 13 into each gap between the adjacent mounting legs 22, 22 or between the mounting leg 22 and the write control terminal 11 in this manner, attachment strength of the IC device 7, the write control terminals 11 and the mounting legs 22 to the supporting substrate 26 can be increased. In addition, the resin material 13 provides a favorable protection of the circuit formation surface of the IC device 7, leading to the increased mechanical strength and reliability of the temperature-compensated quartz-crystal oscillator.

In the case where the resin material 13 is formed from a transparent material, even when the side faces of the IC device 7 exposed to outside from between the adjacent mounting legs 22 are coated with the resin material 13, a junction between the IC device 7 and the supporting substrate 26 can be directly observed through the transparent resin material 13. In product inspection, therefore, bonded conditions of the IC device 7 can be readily checked by visual inspection or the like. This also contributes to the improved workability of the inspection.

Further, the outer periphery of the resin material 13 extends to the attachment region of the write control terminals 11 and is deposited on the bottom faces of the write control terminals. This ensures a certain distance between wiring of the motherboard on which the temperature-compensated quartz-crystal oscillator is implemented and the write control terminals 11. As a result, occurrence of a large stray capacitance can be prevented. Further, the resin material 13 exists between the lower ends of the write control terminals 11 and wiring of the motherboard. When the temperature-compensated quartz-crystal oscillator is mounted on the motherboard, therefore, the problem that part of the molten solder comes in contact with the write control terminals 11 and causes a short-circuit can be effectively prevented. This leads to an easy handling of the temperature-compensated quartz-crystal oscillator.

FIG. 10 is a bottom view illustrating a variant of the temperature-compensated quartz-crystal oscillator in accordance with the above-mentioned second embodiment. In the above-mentioned embodiment, a plurality of the write control terminals 11 are divided into two groups and the groups are arranged along the two sides of the supporting substrate 26, which are parallel to each other, respectively. On the contrary, in the variant shown in FIG. 10, a plurality of write control terminals 11 are aligned along a side 26B of the supporting substrate 26. In this case, a space is generated between the mounting legs 22, 22 disposed at both ends of a side 26A opposed to the side 26B. A chip component (electronic devices other than the IC device) such as a chip capacitor may be disposed in the space. In this case, since the free space on the bottom face of the supporting substrate 26 is utilized more efficiently, the temperature-compensated quartz-crystal oscillator can be reduced in size.

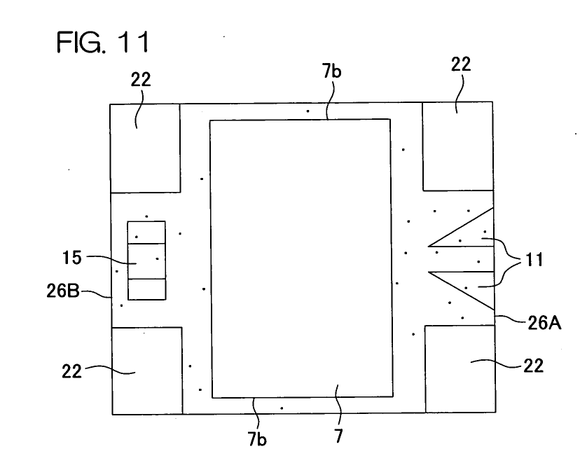

FIG. 11 is a bottom view illustrating another variant of the temperature-compensated quartz-crystal oscillator in accordance with the above-mentioned second embodiment. In this variant, as in the case of FIG. 10, the write control terminals 11 are aligned along the side 26A of the supporting substrate 26 and no write control terminal 11 is provided in the vicinity of the side 26B opposed to the above-mentioned side 26A. In a space defined between the mounting legs 22, 22 disposed at both ends of the side 26B, a chip component (electronic devices other than the IC device) such as the chip capacitor 15 is attached to the top face of the supporting substrate 26.

This variant is characterized by the shape of the write control terminals 11. Like the mounting legs 22, the write control terminals 11 each are shaped as a metal post in the shape of a triangle pole by processing a metal material such as copper using a conventionally known photoetching method. The length dimension of the write control terminal 11 is set slightly short so that its lower end is located upper than the lower end of the mounting leg 22. The write control terminals 11 are fixed to the top face of the supporting substrate 26 so that part of each side face is exposed to outside from between the adjacent mounting legs 22.

A particularly important feature of this variant is that each gap between the write control terminal 11 like a triangle pole and the side face of the mounting leg 12 is set to become narrower from the side of the IC device 7 toward the side of the edge of the supporting substrate 26. Accordingly, when the IC device 7 is sealed with the resin material 13, the liquid resin material 13 can be favorably penetrated and poured into each gap between the mounting gap 22 and the write control terminal 11. As a result, by favorably letting (preferably, filling) the resin material 13 into the gap between the mounting gap 12 and the write control terminal 11, attachment strength of the write control terminals 11 and the mounting gap 22 to the supporting substrate 26 can be increased more effectively.

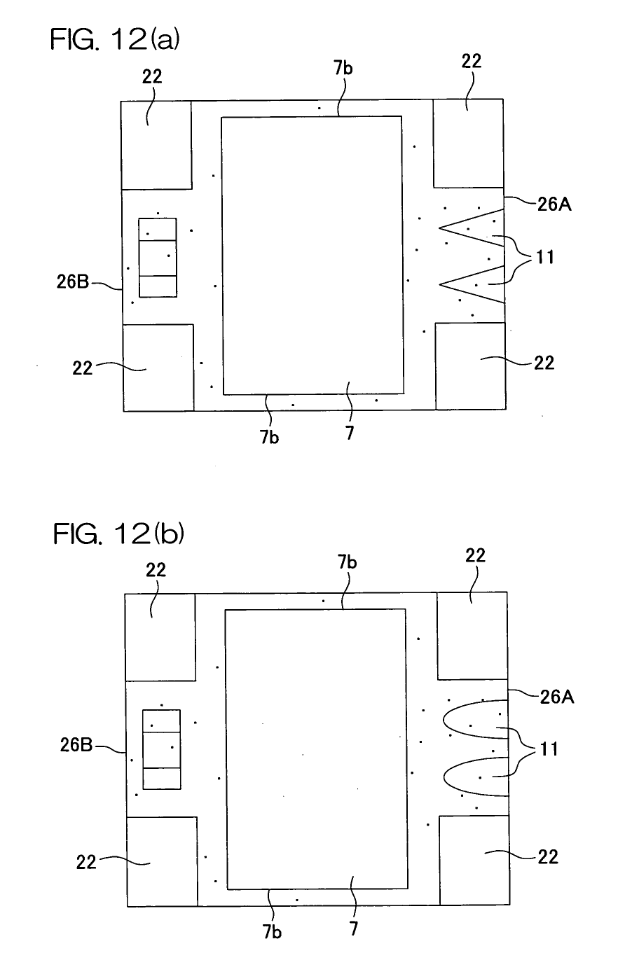

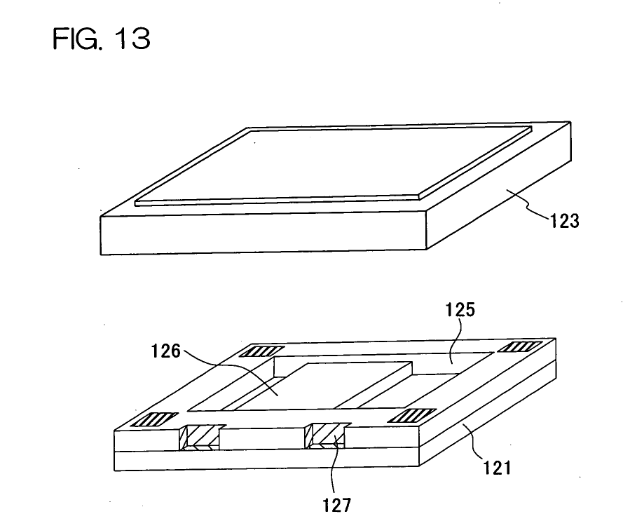

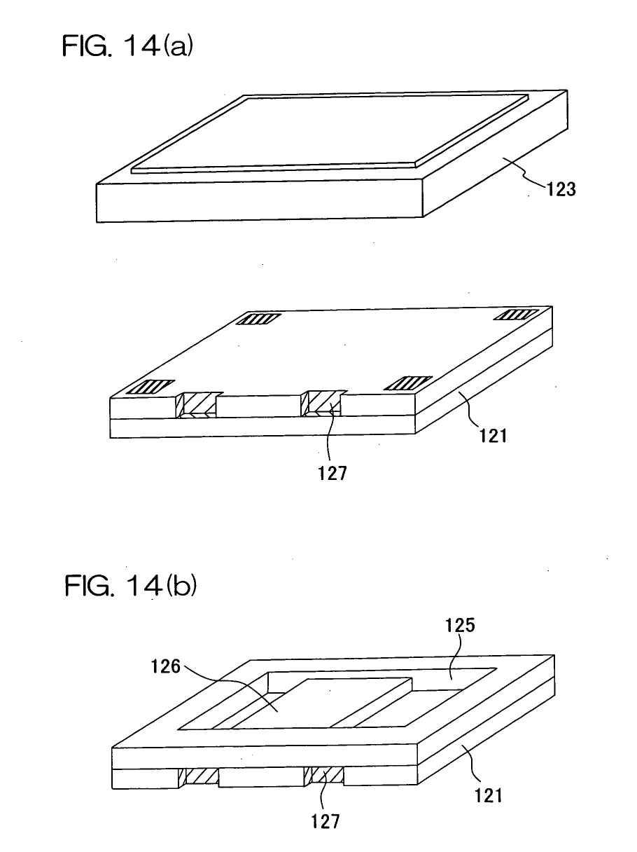

In the example shown in FIG. 11, opposing side faces of the adjacent write control terminals 11 are parallel to each other. Instead of this, as shown in FIG. 12, a distance between the opposing side faces of the adjacent write control terminals 11 may be set to become greater from the outer side toward the inner side of the supporting substrate 26. In this case, the resin material 13 can be readily and rapidly poured into the gap between the adjacent write control terminals 11. This results in more productive filling of the resin material 13 and more effective improvement in attachment strength of the write control terminals 11 to the supporting substrate 6.

Further, the write control terminals 11 having a shape other than a triangle pole can achieve the similar effect. For example, the write control terminals 11 each may be formed of a metal post in the shape of a semicircular column as shown in FIG. 12(b) or of a square pole having a bottom face of trapezoid.

The following modifications may be made to the above-mentioned second embodiment.

For example, in the above-mentioned embodiment, the mounting legs 22 each are formed of a metal post. Instead of this, however, the mounting legs 22 may be formed integral with the supporting substrate 26 by using the same insulating material as that of the supporting substrate 26. In this case, external terminals for connecting the temperature-compensated quartz-crystal oscillator to an external wiring substrate such as a motherboard are formed in a film on the bottom faces of the mounting legs 22. Further, it is preferred that wiring conductors for electrically connecting the connection pads with the wiring conductors 26a on the supporting substrate 26 are formed on the top faces and side faces of the mounting legs 22.

The conductive bonding material used for bonding the IC device 7, the write control terminals 11 and the mounting legs 22 to the bottom face of the supporting substrate 26 is not limited to a general conductive material such as solder. For example, an aristropic conductive bonding material may be used as the conductive bonding material. In this case, attachment operation of the IC device 7, the mounting legs 22 and the like to the supporting substrate 26 becomes extremely simple and hence, the assembling process of the temperature-compensated quartz-crystal oscillator is further simplified.

In the above-mentioned embodiment, four mounting legs members 12 are attached at four corners on the top face of the supporting substrate 26. However, the number of the spacer members 12 is not limited to four. For example, in the case where the mounting leg 22 is formed from the same insulating material as that of the supporting substrate 26, the supporting substrate 26 may be supported by one mounting leg 22 formed in the shape of U along the outer periphery of the mounting leg 22. In this case, the write control terminal 11 may be disposed in a gap defined by the mounting leg 22 in the shape of U on the outer periphery of the supporting substrate 26. As a matter of course, the supporting substrate 26 may be supported by two, three, five or more mounting legs 22.

The following modifications may be made to the first and second embodiments.

Furthermore, in the above-mentioned embodiments, the number of the write control terminals is set to be 2N, more specifically four. Instead of this, however, the number of the write control terminals may be two, six or any odd-number such as three or five.

Furthermore, in the above-mentioned embodiment, the closure 4 of the package 1 is bonded to the substrate 2 via the seal ring 3. However, an alternative approach may be taken. That is, a metallize pattern for bonding is formed on the top face of the substrate 2 and the closure 4 is directly welded to the metallize pattern.

Furthermore, in the above-mentioned embodiment, the seal ring 3 is directly attached to the top face of the substrate 2 of the package 1. However, an alternative approach may be taken. That is, a frame body formed from the same ceramic material as the substrate 2 is integrally attached on the top face of the substrate 2 and then the seal ring 3 is attached on the top face of the frame body.

While the embodiments of the present invention have been described in detail, these embodiments are only illustrative examples for clarifying technical concepts of the present invention and hence, the present invention should not be construed based on only the illustrative examples. The sprit and scope of the present invention is limited by the appended claims.

This application corresponds to Japanese Patent Application No. 2004-190923 filed to Japan Patent Office on Jun. 29, 2004, Japanese Patent Application No. 2004-020786 filed to Japan Patent Office on Jan. 29, 2004, Japanese Patent Application No. 2004-190922 filed to Japan Patent Office on Jun. 29, 2004, Japanese Patent Application No. 2004-22284 filed to Japan Patent Office on Jan. 29, 2004 and Japanese Patent Application No. 2004-20785 filed to Japan Patent Office on Jan. 29, 2004. Disclosure of these applications shall be incorporated hereto by reference.

1. A temperature-compensated quartz-crystal oscillator comprising:
a quartz-crystal oscillation device;
a package for accommodating said quartz-crystal oscillation device therein;
an IC device for controlling an oscillation output based on a resonant frequency of said quartz-crystal oscillation device;
a substrate for supporting said package and mounting said IC device thereon; and
a write control terminal formed of a metal body provided on said substrate for writing temperature compensation data into said IC device.

2. A temperature-compensated quartz-crystal oscillator as stated in claim 1, wherein said package and said substrate are formed so as to have the substantially same dimension in a plan view.

3. A temperature-compensated quartz-crystal oscillator as stated in claim 1, wherein
said substrate has a substantially rectangular shape in a plan view,
further includes spacer members each disposed at four corners of said substrate, and
said write control terminal is disposed between said adjacent spacer members.

4. A temperature-compensated quartz-crystal oscillator as stated in claim 1, wherein
said package is seated on/fixed to said substrate via a spacer member,
said IC device is mounted on the top face of said substrate on the package's side,
said write control terminal is intervened between said package and said substrate and part of the write control terminal is exposed from between the side faces of said package and said substrate.

5. A temperature-compensated quartz-crystal oscillator as stated in claim 4 further comprising a resin material that seals said IC device and has an extension that extends to the outer periphery of said substrate on its outer periphery, wherein
said spacer member has a gap along the top face of said substrate, and
said extension of said resin material enters into the gap of said spacer member and the gap between said spacer member and said write control terminal.

6. A temperature-compensated quartz-crystal oscillator as stated in claim 5, wherein
said write control terminal is disposed in the gap of said spacer member between said package and said substrate,
a distance between the side faces of said write control terminal and said spacer member is set to become greater from the outer side toward the inner side of said substrate, and
part of said resin material is poured into the gap between said spacer member and said write control terminal.

7. A temperature-compensated quartz-crystal oscillator as stated in claim 5, wherein
a plurality of said write control terminals are disposed in the gap of said spacer member between said package and said substrate,
a distance between the side faces of said adjacent write control terminals is set to become greater from the outer side toward the inner side of said substrate, and
part of said resin material is poured into the gap between said adjacent write control terminals.

8. A temperature-compensated quartz-crystal oscillator as stated in claim 4 further comprising a connection pad provided on the bottom face of said package, wherein
an upper end of said write control terminal is bonded to said connection pad via a bonding material, thereby achieving mechanical connection of said write control terminal and said package.

9. A temperature-compensated quartz-crystal oscillator as stated in claim 4, wherein
said substrate has a substantially rectangular shape in a plan view, and
said spacer members are comprised of four metal bodies each attached at four corners of the top face of said substrate on the package's side.

10. A temperature-compensated quartz-crystal oscillator as stated in claim 4, wherein
said substrate has a substantially rectangular shape in a plan view,
the number of said write control terminals is set to be 2N (N is natural number), and
said 2N write control terminals are disposed in N along two sides of the substrate, which are parallel to each other, symmetrically with respect to a center line parallel to the above-mentioned two sides.

11. A temperature-compensated quartz-crystal oscillator as stated in claim 1, wherein
said package is fixed to the top face of said substrate,
said IC device is mounted on the bottom face of said substrate,
spacer member is attached to the bottom face of said substrate, and
said write control terminal is attached on an area wherein no spacer member exists in an outer periphery of the bottom face of said substrate, apart from said spacer member.

12. A temperature-compensated quartz-crystal oscillator as stated in claim 11 further comprising a resin material that seals said IC device and has an extension that extends to the outer periphery of said substrate on its outer periphery, wherein
said spacer member have a gap along the bottom face of said substrate, and
said extension of said resin material enters into the gap of said spacer member and the gap between said spacer member and said write control terminal.

13. A temperature-compensated quartz-crystal oscillator as stated in claim 12, wherein
said write control terminal is disposed in the gap of said spacer member in an outer periphery on the bottom face of said substrate,
a distance between the side faces of said write control terminal and said spacer member is set to become greater from the outer side toward the inner side of said substrate, and
part of said resin material is poured into the gap between said spacer member and said write control terminal.

14. A temperature-compensated quartz-crystal oscillator as stated in claim 12, wherein
a plurality of said write control terminals are disposed in the gap of said spacer member in an outer periphery on the bottom face of said substrate,
a distance between the side faces of said adjacent write control terminals is set to become greater from the outer side toward the inner side of said substrate, and
part of said resin material is poured into the gap between said adjacent write control terminals.

15. A temperature-compensated quartz-crystal oscillator as stated in claim 11, wherein
a lower end of said write control terminal is located upper than a lower end of said spacer member and coated with an extension of said resin material.

16. A temperature-compensated quartz-crystal oscillator as stated in claim 11, wherein
said substrate has a substantially rectangular shape in a plan view, and
said spacer members are comprised of four metal bodies each attached at four corners on the bottom face of said substrate.

17. A temperature-compensated quartz-crystal oscillator as stated in claim 11, wherein
said has a substantially rectangular shape in a plan view,
the number of said write control terminals is set to be 2N (N is natural number), and
said 2N write control terminals are disposed in N along two sides of the substrate, which are parallel to each other, symmetrically with respect to a center line parallel to the above-mentioned two sides.
